(19) United States
(12) Patent Application Publication
(10) Pub. No.: US 2025/0210354 A1
(43) Pub. Date: Jun. 26, 2025

(54) MANUFACTURING METHOD OF SEMICONDUCTOR DEVICE

(71) Applicant: DB HiTek Co., Ltd., Seoul (KR)

(72) Inventors: Won Kook CHO, Bucheon-si (KR); Myeong Bum PYUN, Bucheon-si (KR)

(73) Assignee: DB HiTek Co., Ltd., Seoul (KR)

(21) Appl. No.: 18/441,435

(22) Filed: Feb. 14, 2024

(30) Foreign Application Priority Data
Dec. 26, 2023 (KR) 10-2023-0190853

(51) Int. Cl. H01L 21/265; H01L 21/266; H01L 29/06; H01L 29/66

(52) U.S. Cl. CPC H01L 21/26513; H01L 21/266; H10D 30/0295; H10D 62/111

(57) ABSTRACT

A method of manufacturing a semiconductor device, comprising the steps of: forming a mask pattern on a substrate, performing a first ion implantation for a body region and a first impurity region in the substrate by using the mask pattern, forming a first gate electrode and a second gate electrode spaced apart from each other on the substrate, performing a first thermal process on the substrate and forming the body region and the first impurity region, and forming a contact extending to the first impurity region between the first gate electrode and the second gate electrode.

### CROSS-REFERENCE TO RELATED APPLICATION

This application claims priority under 35 U.S.C § 119 to Korean Patent Application No. 10-2023-0190853 filed on Dec. 26, 2023, in the Korean Intellectual Property Office, the entire contents of which are hereby incorporated by reference.

### TECHNICAL FIELD

The disclosure relates to a method of manufacturing a semiconductor device.

### BACKGROUND

The contents set forth in this section merely provide background information on the present embodiments and do not constitute prior art.

In semiconductor devices, particularly SJMOSFETs (Super Junction MOSFETs), the effective channel region can affect the threshold voltage characteristics.

If an ion implantation process for the body region that determines the effective channel region and an ion implantation process for the impurity region are performed using different mask patterns, asymmetry in the effective channel region may be caused by process distribution from the ion implantation, which results in a problem of affecting the threshold voltage characteristics.

### SUMMARY

It is an object of the present disclosure to provide a method of manufacturing a semiconductor device that reduces the threshold voltage distribution of the semiconductor device.

The objects of the present disclosure are not limited to the objects mentioned above, and other objects and advantages of the present disclosure that have not been mentioned can be understood by the following description and will be more clearly understood by the embodiments of the present disclosure. Further, it will be readily appreciated that the objects and advantages of the present disclosure may be realized by the means set forth in the claims and combinations thereof.

The method of manufacturing a semiconductor device of the present disclosure can reduce the threshold voltage distribution by using the same mask pattern in the ion implantation processes for forming the body region and the impurity region.

According to some aspects of the disclosure, a method of manufacturing a semiconductor device, comprising the steps of: forming a mask pattern on a substrate; performing a first ion implantation for a body region and a first impurity region in the substrate by using the mask pattern, forming a first gate electrode and a second gate electrode spaced apart from each other on the substrate; performing a first thermal process on the substrate and forming the body region and the first impurity region, and forming a contact extending to the first impurity region between the first gate electrode and the second gate electrode.

According to some aspects, a second ion implantation step for forming a second impurity region within the first impurity region after the first thermal process is performed.

According to some aspects, the first impurity region is formed within the body region, and the second impurity region is formed within the first impurity region.

According to some aspects, the second ion implantation step is performed, resulting in a channel region being formed in a portion of the body region that overlaps with the first gate electrode and the second gate electrode in a first direction and overlaps with each of the first impurity region and the second impurity region in a second direction, and the first direction and the second direction are directions that intersect with each other.

According to some aspects, a material implanted to form the body region is of a different type from a material implanted to form the first impurity region and the second impurity region.

According to some aspects, the second ion implantation step is performed using the first gate electrode and the second gate electrode spaced apart from each other as masks.

According to some aspects, the first impurity region is formed within the body region.

According to some aspects, the step of performing the first ion implantation comprises the steps of: performing a first implantation process for the body region; and performing a second implantation process for the first impurity region.

According to some aspects, the second implantation process is performed after the first implantation process is performed.

According to some aspects, in the first implantation process, a first type of material is implanted, and in the second implantation process, a second type of material that is different from the first type is implanted.

According to some aspects, in the first implantation process, boron is implanted, and in the second implantation process, arsenic is implanted.

According to some aspects, further comprising the step of: forming a buffer insulating film on the substrate before forming the mask pattern.

According to some aspects, further comprising the steps of: after the step of performing the first ion implantation is performed, removing the mask pattern; removing the buffer insulating film; and performing a second thermal process on the substrate.

According to some aspects, the second thermal process is performed, resulting in a gate insulating film on the substrate, a pre-body region in the substrate, and a pre-first impurity region in the substrate being formed.

According to some aspects, the first gate electrode and the second gate electrode are formed after the pre-body region and the pre-first impurity region are formed in the substrate, and the step of performing the first thermal process is performed on the substrate in which the pre-body region and the pre-first impurity region have been formed.

According to some aspects, the first thermal process is performed, resulting in a channel region being formed in a portion of the body region that overlaps with the first gate electrode and the second gate electrode in a first direction and overlaps with the first impurity region in a second direction, and the first direction and the second direction are directions that intersect with each other.

According to some aspects of the disclosure, a method of manufacturing a semiconductor device, comprising: a first ion implantation step of implanting a first impurity and a second impurity that are different from each other into a substrate, a step of performing a first thermal process for forming a pre-body region by the first impurity and a pre-first impurity region by the second impurity in the substrate, a step of forming a first gate electrode and a second gate electrode spaced apart from each other on the substrate, a step of performing a second thermal process on the pre-body region and the pre-first impurity region and forming a body region and a first impurity region, and a second ion implantation step of forming a second impurity region within the first impurity region.

According to some aspects, the first ion implantation step comprises the steps of: performing a first implantation process of implanting the first impurity; and performing a second implantation process of implanting the second impurity after implanting the first impurity.

According to some aspects, further comprising the step of: forming a gate insulating film on the substrate by using the first thermal process after the first ion implantation step is performed.

According to some aspects of the disclosure, a method of manufacturing a semiconductor device, comprising the steps of: forming a buffer insulating film on a substrate; forming a mask pattern on the buffer insulating film; implanting a first impurity for a body region into the substrate by using the mask pattern, implanting a second impurity for a first impurity region into the substrate after implanting the first impurity, removing the mask pattern and the buffer insulating film, performing a first thermal process on the substrate, forming a pre-body region and a pre-first impurity region in the substrate, and forming a gate insulating film on the substrate, forming a first gate electrode and a second gate electrode spaced apart from each other on the gate insulating film; performing a second thermal process on the substrate in which the pre-body region and the pre-first impurity region have been formed, and forming the body region and the first impurity region, and implanting a third impurity into a portion of the first impurity region between the first gate electrode and the second gate electrode, with the first gate electrode and the second gate electrode as masks.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

In addition to the contents described above, specific effects of the present disclosure will be described together while describing the following specific details for carrying out the present disclosure.

### BRIEF DESCRIPTION OF THE DRAWINGS

FIG. 1 is a flowchart for describing a method of manufacturing a semiconductor device in accordance with an embodiment of the present disclosure.

FIG. 2 is a diagram for describing the step S100 of FIG. 1.

FIGS. 3 and 4 are diagrams for describing the step S200 of FIG. 1.

FIGS. 5 to 9 are diagrams for describing the step S300 of FIG. 1.

FIGS. 10 to 12 are diagrams for describing the step S400 of FIG. 1.

FIG. 13 is a diagram for describing the step S500 of FIG. 1.

FIG. 14 is a plot for describing the effect of the method of manufacturing a semiconductor device in accordance with an embodiment of the present disclosure.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

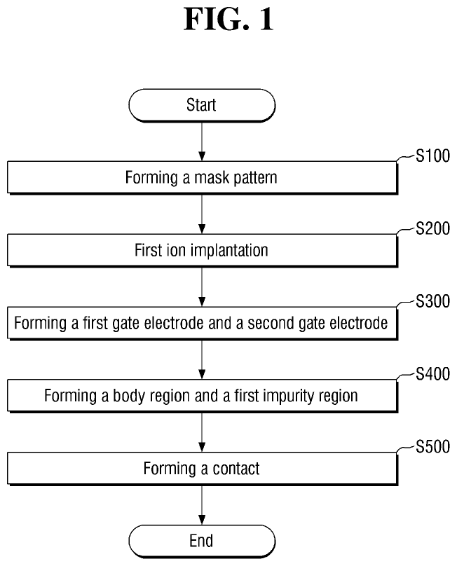

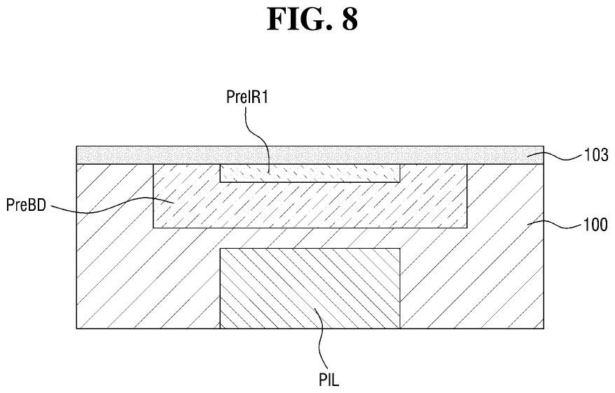

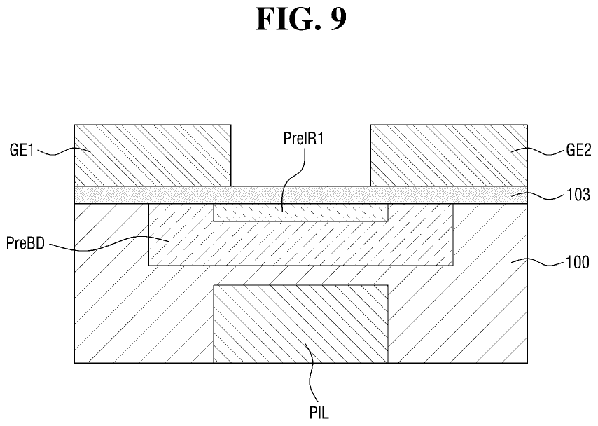

Hereinafter, a method of manufacturing a semiconductor device in accordance with an embodiment of the present disclosure will be described with reference to FIGS. 1 to 14.

FIG. 1 is a flowchart for describing a method of manufacturing a semiconductor device in accordance with an embodiment of the present disclosure.

Referring to FIG. 1, the method of manufacturing a semiconductor device in accordance with an embodiment of the present disclosure may include a step S100 of forming a mask pattern on a substrate.

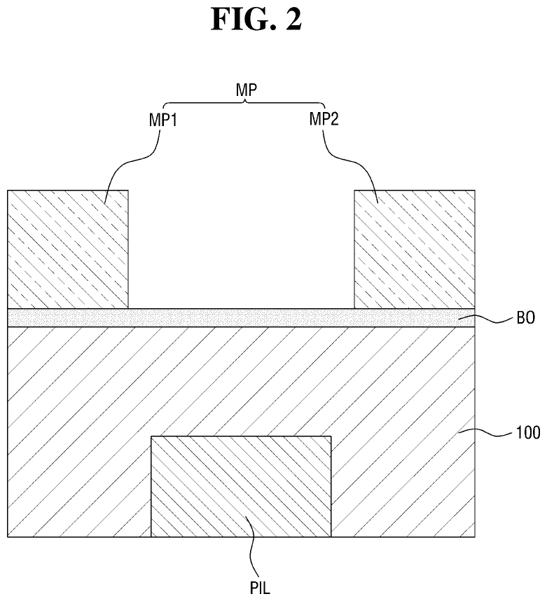

FIG. 2 is a diagram for describing the step S100 of FIG. 1.

Referring to FIGS. 1 and 2, the method of manufacturing a semiconductor device in accordance with an embodiment of the present disclosure may include, first, a step of forming a buffer insulating film BO on a substrate 100. The substrate 100 may have a pillar structure PIL formed thereon.

A mask pattern MP may be formed on the buffer insulating film BO. The mask pattern MP may include a first mask pattern MP1 and a second mask pattern MP2. The first mask pattern MP1 and the second mask pattern MP2 may be formed on the buffer insulating film BO on the substrate 100 while being spaced apart from each other. The first mask pattern MP1 and the second mask pattern MP2 may be photoresist.

Referring again to FIG. 1, the method of manufacturing a semiconductor device in accordance with an embodiment of the present disclosure may include a step S200 of performing a first ion implantation into the substrate. The first ion implantation process may be a step performed to form a body region and a first impurity region in the substrate by using a mask pattern.

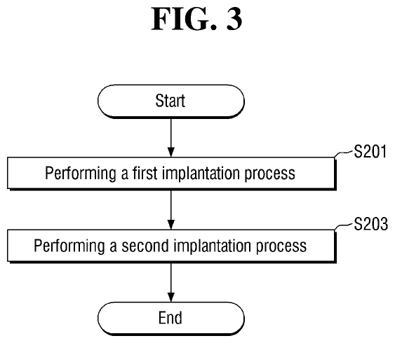

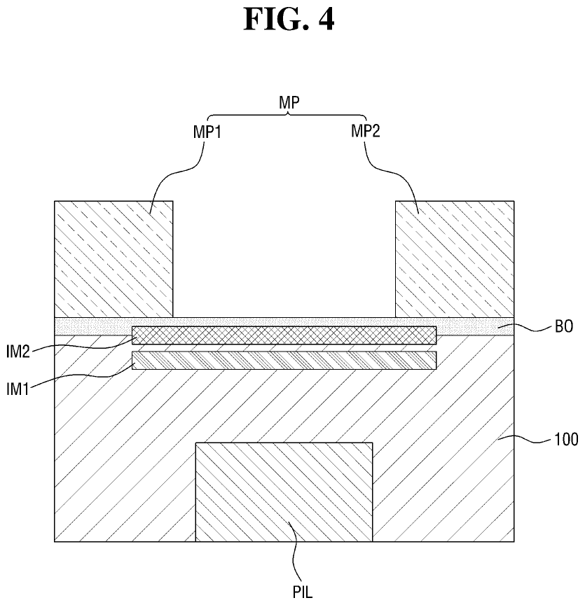

FIGS. 3 and 4 are diagrams for describing the step S200 of FIG. 1.

Referring to FIGS. 1, 3, and 4, the step S200 of performing the first ion implantation in the method of manufacturing a semiconductor device in accordance with an embodiment of the present disclosure may include a step S201 of performing a first implantation process and a step S203 of performing a second implantation process.

The first implantation process may be to implant a first impurity into the substrate 100 in order to form a body region in the substrate 100. In the first implantation process, a first type of material may be implanted into the substrate 100 in order to form the body region. The first implantation process may be performed, so that a first impurity implantation region IM1 in which the first type of material has been implanted into the substrate 100 can be formed. The first type of material may be, for example, a p-type impurity. The first type of material may be boron, for example.

The second implantation process may be to implant a second impurity into the substrate 100 in order to form a first impurity region in the substrate 100. The second implantation process may be performed after the first implantation process is performed. In the second implantation process, a second type of material that is different from the first type may be implanted into the substrate 100 in order to form the first impurity region. The second implantation process may be performed, so that a second impurity implantation region IM2 in which the second type of material has been implanted into the substrate 100 can be formed. The second type of material may be, for example, an n-type impurity. The second type of material may be arsenic, for example.

The first ion implantation step S200 including the first implantation process and the second implantation process may all be performed using the first mask pattern MP1 and the second mask pattern MP2. The first and second impurities may be implanted mainly into the part of the buffer insulating film BO and the substrate 100 exposed by the first mask pattern MP1 and the second mask pattern MP2.

The second impurity implantation region IM2 may be formed on the first impurity implantation region IM1. In the drawings, the second impurity implantation region IM2 is shown as partially overlapping the buffer insulating film BO, but is not limited thereto. As a matter of course, the buffer insulating film BO may also be formed on the second impurity implantation region IM2 so that they do not overlap each other depending on the process.

Referring again to FIG. 1, the method of manufacturing a semiconductor device in accordance with an embodiment of the present disclosure may include a step S300 of forming a first gate electrode and a second gate electrode on the substrate. The first gate electrode and the second gate electrode may be formed to be spaced apart from each other.

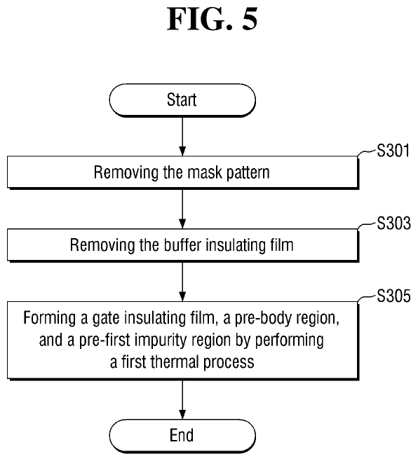

FIGS. 5 to 9 are diagrams for describing the step S300 of FIG. 1.

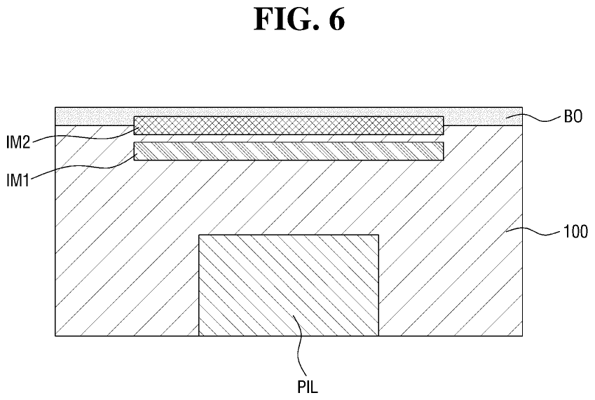

Referring to FIGS. 5 and 6, the step S300 of forming the first gate electrode and the second gate electrode on the substrate 100 may include a step S301 of removing the mask pattern (MP in FIG. 4). After the first ion implantation step S200 is performed, the mask pattern (MP in FIG. 4) may be removed. As the mask pattern (MP in FIG. 4) is removed, the buffer insulating film BO may be exposed.

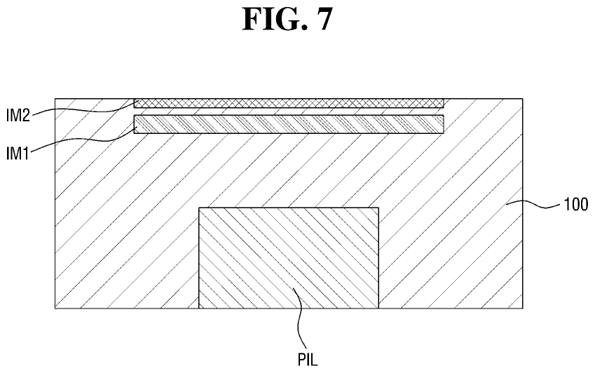

Referring to FIGS. 5 and 7, the step S300 of forming the first gate electrode and the second gate electrode on the substrate 100 may include a step S303 of removing the buffer insulating film BO. As the buffer insulating film BO is removed, the second impurity implantation region IM2 may be exposed.

Referring to FIGS. 5, 8, and 9, the step S300 of forming the first gate electrode and the second gate electrode on the substrate 100 may include a step S305 of forming a gate insulating film 103, a pre-body region PreBD, and a pre-first impurity region PreIR1 by performing a first thermal process.

The gate insulating film 103 may be formed on the substrate 100. In order to form the gate insulating film 103, a first thermal process may be performed. With the first thermal process, the first impurity in the first impurity implantation region IM1 may diffuse, resulting in the pre-body region PreBD being formed in the substrate 100. With the first thermal process, the second impurity in the second impurity implantation region IM2 may diffuse, resulting in the pre-first impurity region PreIR1 being formed in the substrate 100.

The pre-first impurity region PreIR1 may be formed within the pre-body region PreBD. The pre-first impurity region PreIR1 may be formed by diffusing the second impurity so as to occupy part of the pre-body region PreBD.

In the drawings, the pre-body region PreBD is shown as not diffusing up to the pillar structure PIL, but is not limited thereto. As a matter of course, the first impurity in the first impurity implantation region IM1 may diffuse with the first thermal process, and the pre-body region PreBD may thus be diffused and formed up to the pillar structure PIL.

After the gate insulating film 103, the pre-body region PreBD, and the pre-first impurity region PreIR1 are formed at S305, a first gate electrode GE1 and a second gate electrode GE2 may be formed on the gate insulating film 103. The first gate electrode GE1 and the second gate electrode GE2 may be formed to be spaced apart from each other. As the first gate electrode GE1 and the second gate electrode GE2 may be spaced apart from each other, a portion of the gate insulating film 103 may be exposed. A portion of each of the first gate electrode GE1 and the second gate electrode GE2 may be formed to overlap the pre-body region PreBD.

Referring again to FIG. 1, the method of manufacturing a semiconductor device in accordance with an embodiment of the present disclosure may include a step S400 of forming a body region and a first impurity region.

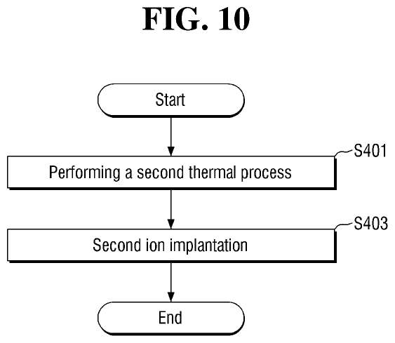

FIGS. 10 to 12 are diagrams for describing the step S400 of FIG. 1.

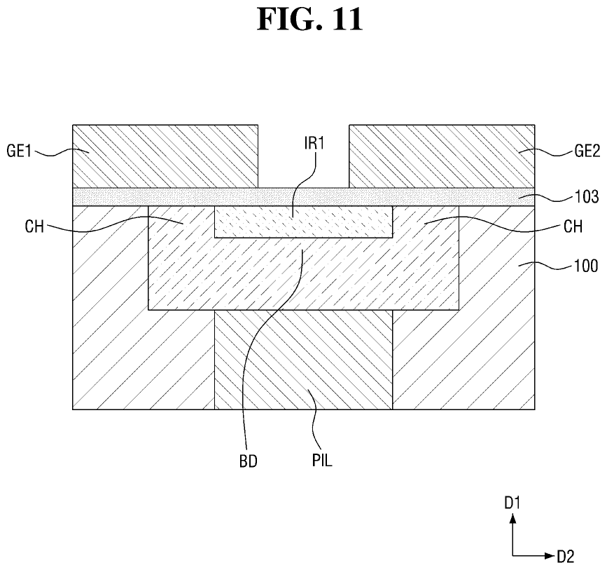

Referring to FIGS. 10 and 11, the step S400 of forming the body region BD and the first impurity region IR1 may include a step S401 of performing a second thermal process on the substrate 100.

The second thermal process may be performed on the substrate 100 in which the pre-body region PreBD and the pre-first impurity region PreIR1 have been formed. With the second thermal process, the first impurity in the pre-body region PreBD may further diffuse, resulting in the body region BD being formed. The body region BD may extend to the pillar structure PIL, for example.

With the second thermal process, the second impurity in the pre-first impurity region PreIR1 may further diffuse, resulting in the first impurity region IR1 being formed. The first impurity region IR1 may be formed within the body region BD.

Due to the difference in diffusion rates between the first impurity and the second impurity, there may arise a difference between the thickness of the body region BD in a first direction D1 and the thickness of the first impurity region IR1 in the first direction D1. The thickness of the body region BD in the first direction D1 may be greater than the thickness of the first impurity region IR1 in the first direction D1.

In addition, due to the difference in diffusion rates between the first impurity and the second impurity, there may arise a difference between the width of the body region BD in a second direction D2 and the width of the first impurity region IR1 in the second direction D2. The width of the body region BD in the second direction D2 may be greater than the width of the first impurity region IR1 in the second direction D2. The first direction D1 and the second direction D2 may be directions that intersect with each other.

With the body region BD and the first impurity region IR1 formed, a channel region CH may be formed. The channel region CH may be a partial region of the body region BD. The channel region CH may be a part of the body region BD that overlaps with each of the first gate electrode GE1 and the second gate electrode GE2 in the first direction D1 and overlaps with the first impurity region IR1 in the second direction D2.

The channel region CH may be formed in portions of the body region BD on both sides based on the first impurity region IR1. Each of the channel regions CH formed in portions of the body region BD on both sides based on the first impurity region IR1 may be symmetrical to each other.

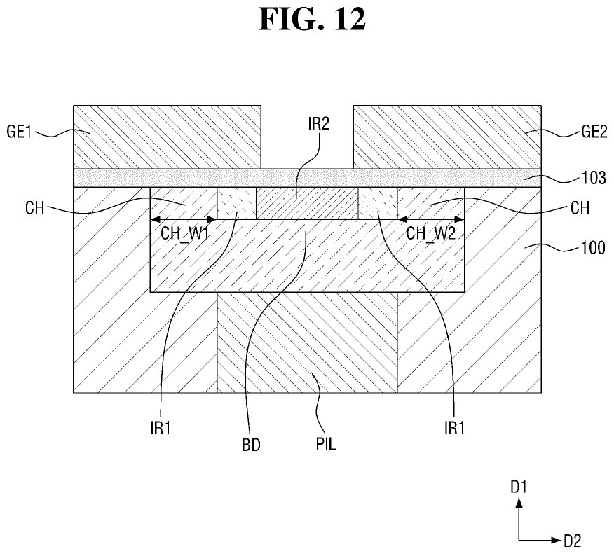

Referring to FIGS. 10 and 12, the step S400 of forming the body region BD and the first impurity region IR1 may include a step S403 of performing a second ion implantation.

The second ion implantation may be performed with the first gate electrode GE1 and the second gate electrode GE2 as masks. The second ion implantation process may be to implant a third impurity into a portion of the first impurity region IR1 between the first gate electrode GE1 and the second gate electrode GE2. The second ion implantation process may be to implant a third impurity in order to form a second impurity region IR2 within the first impurity region IR1 after the second thermal process is performed. The second impurity in the first ion implantation step for the first impurity region IR1 and the third impurity in the second ion implantation step for the second impurity region IR2 may be the same type of material. For example, the second impurity may be arsenic and the third impurity may be phosphorus.

The second impurity region IR2 may occupy a portion of the first impurity region IR1. The second impurity region IR2 may be formed in the first impurity region IR1 between the first gate electrode GE1 and the second gate electrode GE2.

Referring again to FIG. 1, the method of manufacturing a semiconductor device in accordance with an embodiment of the present disclosure may include a step S500 of forming a contact.

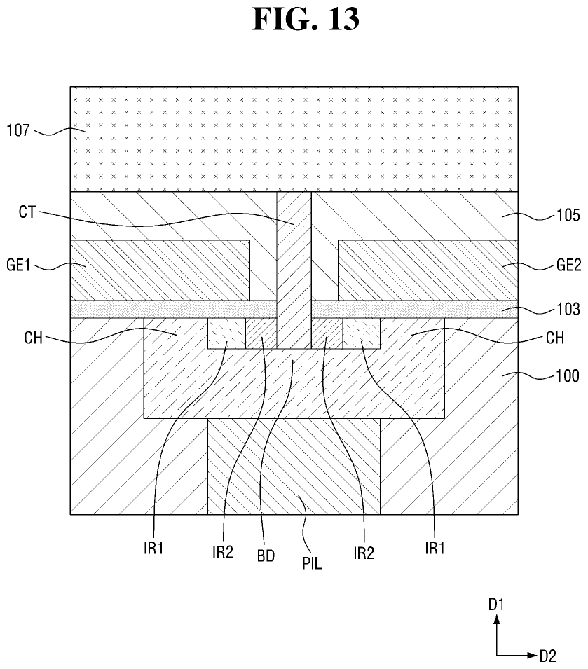

FIG. 13 is a diagram for describing the step S500 of FIG. 1.

Referring to FIGS. 1 and 13, after the second ion implantation for the second impurity region IR2 is performed, a contact CT extending to the first impurity region IR1 may be formed between the first gate electrode GE1 and the second gate electrode GE2. The contact CT may penetrate the first impurity region IR1 and the second impurity region IR2.

An interlayer insulating film 105 may be formed on the first gate electrode GE1, the second gate electrode GE2, and the contact CT. The interlayer insulating film 105 may be formed to cover the first gate electrode GE1, the second gate electrode GE2, and the contact CT. A metal layer 107 may be formed on the interlayer insulating film 105.

The method of manufacturing a semiconductor device in accordance with an embodiment of the present disclosure can compensate for the concentration of impurities by performing the first ion implantation process and the second ion implantation process, thereby further implanting the third impurity of the same type (e.g., n-type impurity) into the first impurity region IR1. If the concentration of impurities is compensated, the resistance can be reduced.

The method of manufacturing a semiconductor device in accordance with an embodiment of the present disclosure can allow the channel region CH to be formed symmetrically by implanting the first impurity for the body region and the second impurity for the first impurity region by using the same mask pattern MP in the first ion implantation step. In other words, the widths CH_W1 and CH_W2 of each of the channel regions CH formed on both sides of the first impurity region IR1 and the second impurity region IR2 may be substantially the same. For example, the widths CH_W1 and CH_W2 of each of the channel regions CH formed on both sides of the first impurity region IR1 and the second impurity region IR2 may have a difference within a minimum error range. For example, the widths CH_W1 and CH_W2 of each of the channel regions CH formed on both sides of the first impurity region IR1 and the second impurity region IR2 may be the same as each other.

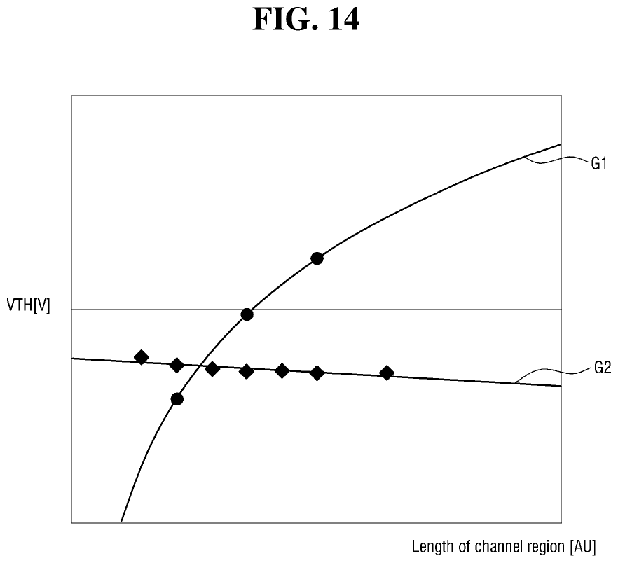

FIG. 14 is a plot for describing the effect of the method of manufacturing a semiconductor device in accordance with an embodiment of the present disclosure.

Referring to FIG. 14, the first graph G1 is a graph showing the distribution of the threshold voltage VTH according to the existing method of manufacturing a semiconductor device, and the second graph G2 is a graph showing the distribution of the threshold voltage VTH according to the method of manufacturing a semiconductor device in accordance with an embodiment of the present disclosure. The x-axis may be the length of the channel region (unit: AU (arbitrary unit)), and the y-axis may be VTH (unit: V (voltage)).

In the existing method of manufacturing a semiconductor device, each of the impurity implantation process for the body region and the impurity implantation process for the first impurity region may be performed using different mask patterns.

It can be seen that the second graph G2 has a smaller change in threshold voltage VTH compared to the first graph G1. The method of manufacturing a semiconductor device in accordance with an embodiment of the present disclosure can ensure the stability of the semiconductor device by reducing the distribution of the threshold voltage VTH.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A method of manufacturing a semiconductor device, comprising the steps of:
forming a mask pattern on a substrate;
performing a first ion implantation for a body region and a first impurity region in the substrate by using the mask pattern;
forming a first gate electrode and a second gate electrode spaced apart from each other on the substrate;
performing a first thermal process on the substrate and forming the body region and the first impurity region; and
forming a contact extending to the first impurity region between the first gate electrode and the second gate electrode.

2. The method of claim 1, further comprising:
performing a second ion implantation step for forming a second impurity region within the first impurity region after the first thermal process is performed.

3. The method of claim 2, wherein the first impurity region is formed within the body region, and
the second impurity region is formed within the first impurity region.

4. The method of claim 3, wherein the second ion implantation step is performed, resulting in a channel region being formed in a portion of the body region that overlaps with the first gate electrode and the second gate electrode in a first direction and overlaps with each of the first impurity region and the second impurity region in a second direction, and
the first direction and the second direction are directions that intersect with each other.

5. The method of claim 2, wherein a material implanted to form the body region is of a different type from a material implanted to form the first impurity region and the second impurity region.

6. The method of claim 2, wherein the second ion implantation step is performed using the first gate electrode and the second gate electrode spaced apart from each other as masks.

7. The method of claim 1, wherein the first impurity region is formed within the body region.

8. The method of claim 1, wherein the step of performing the first ion implantation comprises the steps of:
performing a first implantation process for the body region; and
performing a second implantation process for the first impurity region.

9. The method of claim 8, wherein the second implantation process is performed after the first implantation process is performed.

10. The method of claim 8, wherein in the first implantation process, a first type of material is implanted, and
in the second implantation process, a second type of material that is different from the first type is implanted.

11. The method of claim 10, wherein in the first implantation process, boron is implanted, and
in the second implantation process, arsenic is implanted.

12. The method of claim 1, further comprising the step of:
forming a buffer insulating film on the substrate before forming the mask pattern.

13. The method of claim 12, further comprising the steps of:
after the step of performing the first ion implantation is performed,
removing the mask pattern;
removing the buffer insulating film; and
performing a second thermal process on the substrate.

14. The method of claim 13, wherein the second thermal process is performed, resulting in a gate insulating film on the substrate, a pre-body region in the substrate, and a pre-first impurity region in the substrate being formed.

15. The method of claim 14, wherein the first gate electrode and the second gate electrode are formed after the pre-body region and the pre-first impurity region are formed in the substrate, and
the step of performing the first thermal process is performed on the substrate in which the pre-body region and the pre-first impurity region have been formed.

16. The method of claim 1,
wherein the first thermal process is performed,
resulting in a channel region being formed in a portion of the body region that overlaps with the first gate electrode and the second gate electrode in a first direction and overlaps with the first impurity region in a second direction, and
the first direction and the second direction are directions that intersect with each other.

17. A method of manufacturing a semiconductor device, comprising:
a first ion implantation step of implanting a first impurity and a second impurity that are different from each other into a substrate;
a step of performing a first thermal process for forming a pre-body region by the first impurity and a pre-first impurity region by the second impurity in the substrate;
a step of forming a first gate electrode and a second gate electrode spaced apart from each other on the substrate;
a step of performing a second thermal process on the pre-body region and the pre-first impurity region and forming a body region and a first impurity region; and
a second ion implantation step of forming a second impurity region within the first impurity region.

18. The method of claim 17, wherein the first ion implantation step comprises the steps of:
performing a first implantation process of implanting the first impurity; and
performing a second implantation process of implanting the second impurity after implanting the first impurity.

19. The method of claim 17, further comprising the step of:
forming a gate insulating film on the substrate by using the first thermal process after the first ion implantation step is performed.

20. A method of manufacturing a semiconductor device, comprising the steps of:
forming a buffer insulating film on a substrate;
forming a mask pattern on the buffer insulating film;
implanting a first impurity for a body region into the substrate by using the mask pattern;
implanting a second impurity for a first impurity region into the substrate after implanting the first impurity;
removing the mask pattern and the buffer insulating film;
performing a first thermal process on the substrate, forming a pre-body region and a pre-first impurity region in the substrate, and forming a gate insulating film on the substrate;
forming a first gate electrode and a second gate electrode spaced apart from each other on the gate insulating film;
performing a second thermal process on the substrate in which the pre-body region and the pre-first impurity region have been formed, and forming the body region and the first impurity region; and
implanting a third impurity into a portion of the first impurity region between the first gate electrode and the second gate electrode, with the first gate electrode and the second gate electrode as masks.
